(19) United States
(12) Patent Application Publication
(10) Pub. No.: US 2026/0136954 A1
(43) Pub. Date: May 14, 2026

(54) APPARATUS AND METHODS FOR COPPER-NTE (NEGATIVE THERMAL EXPANSION) FILLED THROUGH-GLASS VIAS

(71) Applicant: Intel Corporation, Santa Clara, CA (US)

(72) Inventors: Pratyasha Mohapatra, Hillsboro, OR (US); Pratyush Mishra, Tempe, AZ (US); Benjamin T. Duong, Phoenix, AZ (US); Kari E. Hernandez, Phoenix, AZ (US); Soham Agarwal, Chandler, AZ (US)

(73) Assignee: Intel Corporation, Santa Clara, CA (US)

(21) Appl. No.: 18/948,066

(22) Filed: Nov. 14, 2024

(51) Int. Cl. H01L 23/538; H01L 21/48; H01L 23/498; H01L 25/00; H01L 25/065

(52) U.S. Cl. CPC H10W 70/611; H10W 70/095; H10W 70/635; H10W 70/66; H10W 90/00; H10W 90/297; H10W 90/722

(57) ABSTRACT

Architectures and methods for through-glass vias (TGVs) filled with copper and negative thermal expansion (NTE) material in order to reduce the coefficient of thermal expansion (CTE) of the material in the TGVs. The NTE can be added to an electroplating solution. The desired or target CTE for the fill material in the TGV can be used to inform the selection of the specific NTE to use and the percentage of the NTE to use.

### BACKGROUND

A variety of semiconductor devices implement a glass core within a multi-layer substrate. Electronic communication through the glass core is often facilitated with through-glass vias (TGVs) that are filled with copper. There is a coefficient of thermal expansion (CTE) mismatch between the glass and the copper that can lead to stress and cracking of the glass core. Accordingly, improved architecture and methods for manufacturing the TGVs are desired.

### BRIEF DESCRIPTION OF THE DRAWINGS

FIG. 1 provides simplified cross-sectional illustrations of embodiments of copper-NTE filled through-glass vias, in accordance with various embodiments.

FIGS. 2-3 illustrate various exemplary stages of fabrication of copper-NTE filled through-glass vias, in accordance with various embodiments.

FIGS. 4-6 illustrate exemplary use cases for copper-NTE filled through-glass vias, in accordance with various embodiments.

FIG. 7 illustrates an example method for copper-NTE filled through-glass vias, in accordance with various embodiments.

FIG. 8 is a top view of a wafer and dies that may be included in a microelectronic assembly, in accordance with any of the embodiments disclosed herein.

FIG. 9 is a simplified cross-sectional side view showing an implementation of an integrated circuit on a die that may be included in various embodiments, in accordance with any of the embodiments disclosed herein.

FIG. 10 is a cross-sectional side view of a microelectronic assembly that may include any of the embodiments disclosed herein.

FIG. 11 is a block diagram of an example electrical device that may include any of the embodiments disclosed herein.

### DETAILED DESCRIPTION

A semiconductor package may include a multi-layer substrate with a “glass core” or layer of glass sandwiched therebetween. The layer of glass has perforations therethrough (also called through-vias or through-glass vias (TGVs)) to accommodate routing electrical signals between the silicon substrate on its upper and lower surfaces. The layer of glass provides mechanical/directional stability and rigidity in a semiconductor package and can increase routing density. However, the mismatch between the coefficient of thermal expansion (CTE) of copper used in the TGVs and the glass, and the brittle quality of glass continue to present technical challenges in fabrication and operation.

Some solutions have deposited a buffer or liner layer on the sidewall of the TGVs to improve copper deposition in the TGVs. However, these solutions are vulnerable to bending stress and temperature stress. Additionally, although the TGVs are often illustrated with perpendicular walls, in practice they are more likely to taper from the upper surface to the midpoint and from the lower surface to the midpoint, exhibiting an hourglass shape. This taper, when filled with a conductive material, creates a “pinch point” at the midpoint. The pinch point phenomenon can adversely limit performance and power density.

Embodiments described herein provide a technical solution to these technical challenges in the form of conformal plated through-glass vias. Practice of the architecture and methods described herein can be readily detected with SEM and/or TEM images as described below. These concepts are developed in more detail below.

Example embodiments are hereinafter described in conjunction with the following drawing figures, wherein like numerals denote like elements. Unless otherwise stated, figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

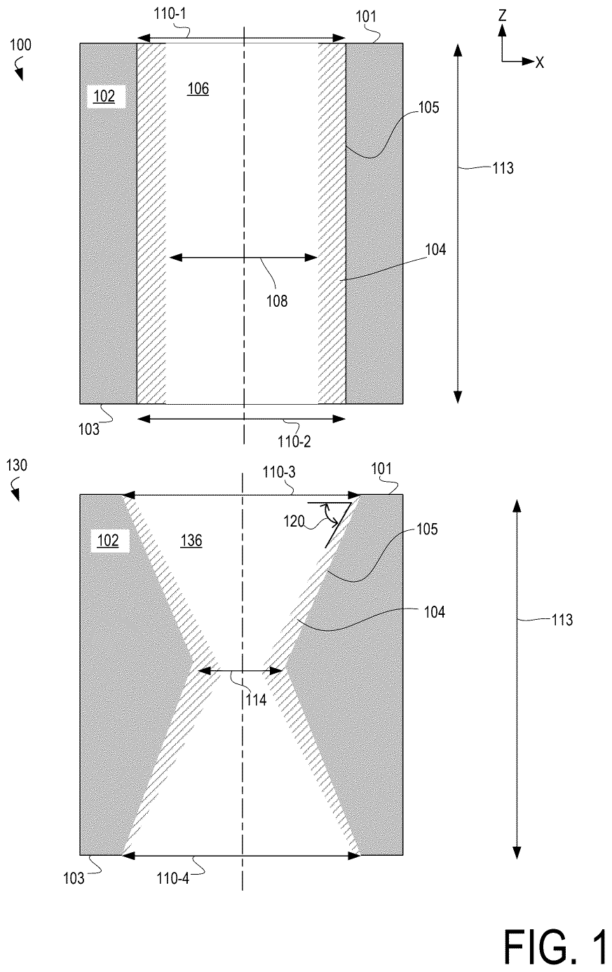

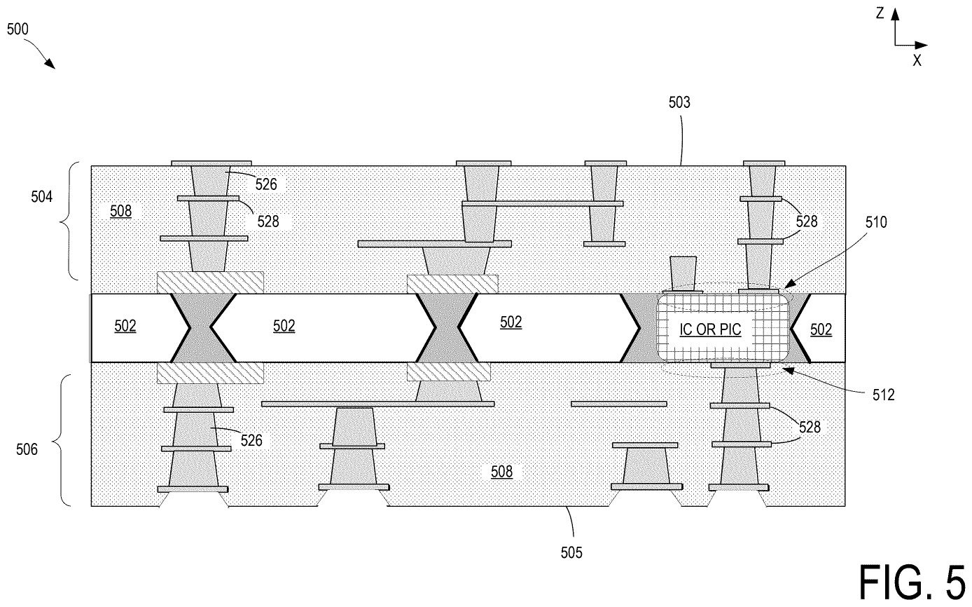

FIGS. 1-7 include many objects that are repeated. Unless otherwise stated, like objects are intended to perform the same function or be the same feature across images, whether labeled or not. Additionally, while the objects in FIGS. 1-7 are not to scale, various relationships and orientations shown in the images are intentional, as described herein.

FIG. 1 provides simplified cross-sectional illustrations of embodiments of conformally plated through-glass vias. The layer of glass 102 or “glass core” may be patterned with a plurality of through-holes, also referred to as through-glass vias (TGVs). Embodiment 100 and embodiment 130 illustrate one of at least one TGVs that may be in the layer of glass 102. The layer of glass 102 has an upper surface 101 and a lower surface 103. The layer of glass 102 may have a thickness 113 (Z height) in a range of 20 microns +/−10% to 2 millimeter +/−10%.

The layer of glass 102 may comprise glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO2, Al2O3, B2O3, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. In some embodiments, the layer of glass 102 or glass core may comprise multiple glass sheets bonded together with an adhesion layer.

At least one through-hole or through-glass via (TGV) is formed in the layer of glass 102 (at 802). The through-holes extend downward from the upper surface 101 to the lower surface 103, with an axis that is orthogonal to the upper surface, as shown. The TGVs are volumes in which glass is removed to fill with electrically conductive fill material, described in more detail below. The through-holes are characterized by a continuous sidewall 105, associated with a first diameter 110-1, 110-3 at the upper surface 101 and the first diameter 110-2, 110-4 at the lower surface 103, and an axis of the through-hole is substantially perpendicular to the upper surface 101 (and also substantially perpendicular to the lower surface 103) of the layer of glass 102, wherein substantially perpendicular is defined as 90 degrees plus or minus 5 degrees. Embodiment 100 illustrates an idealized cylindrical TGV, in which the through-hole has the first diameter 110-1 continuously from the upper surface 101 to the lower surface 103 (in other words, first diameter 110-1 is equal to first diameter 110-2.

In practice, the shape of the TGV reflects the technology used to create it. When the through-hole is created using a laser etch process, the upper surface 101 is laser etched to approximately the midpoint of the layer of glass 102 in the Z-direction and the lower surface 103 is similarly laser etched to the midpoint. The midpoint has a second diameter 114 that is smaller than the first diameter, as illustrated in embodiment 130 (note that the figures are not to-scale but can be relied upon for general spatial relationships). In an embodiment, the second diameter is at least 10% smaller than the first diameter. The midpoint may be halfway between the upper and lower surface, plus or minus 15%. This may result in a TGV with a somewhat hourglass-shaped profile, in which the through-hole narrows as one traces a sidewall 105 toward the midpoint. In this scenario, a slope or taper of the sidewall can be defined by angle 120 measured radially around the axis from the top surface toward the midpoint, and similarly can be measured radially around the axis from the lower surface 103 toward the midpoint.

Embodiments have a conductive layer 104 in the through-holes, the conductive layer is added at 706. The conductive layer 104 is conformal to the sidewall 105 of the cavity 106/136. The conductive layer 104 is continuous from the upper surface 101 to the lower surface 103. The conductive layer 104 does not completely fill the TGV, meaning that a portion of the cavity 106 and cavity 136 remains open from the upper surface 101 to the lower surface 103 after deposition of the conductive layer 104.

Using a chemical vapor deposition (CVD) process, such as for silicon nitride, the conductive layer 104 can be very thin, such as 20 nanometers +/−5 nanometers. In various embodiments, such as embodiment 100 and embodiment 130, the thickness of the conductive layer 104 at any given point along a sidewall can be between 20 nanometers-5 nanometers and 2000 nanometers +5 nanometers. In exemplary embodiment 100, the conductive material has a thickness that remains the same from the upper surface to the lower surface, that thickness being represented by first diameter 110-1 (or diameter 110-2) minus diameter 108, wherein the diameter 108 is the diameter of the cavity 106 that extends continuously from the upper surface 101 to the lower surface 103. The conductive layer 104 can be anywhere between 15 nanometers and 10 microns thick. The thickness of the conductive layer 104 depends on the method used to deposit it.

In embodiment 130, although the image is not to scale, it is intended to show that the thickness of the conductive material may have a thickness that varies slightly between either surface and the midpoint (e.g., may vary from upper surface 101 to midpoint and may vary from lower surface 103 to midpoint); in some scenarios, the conductive material of the conductive layer 104 is thickest around the midpoint and thinnest near the surfaces (the upper surface 101 and at the lower surface 103).

In some embodiments, the conductive material comprises copper. In other embodiments, the conductive material can be titanium nitride, or a similar conductive material.

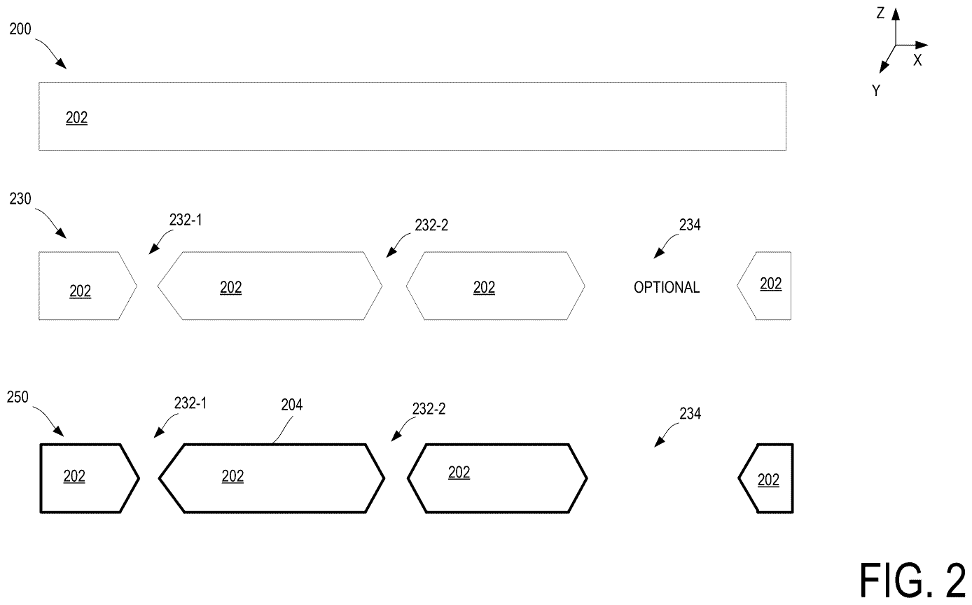

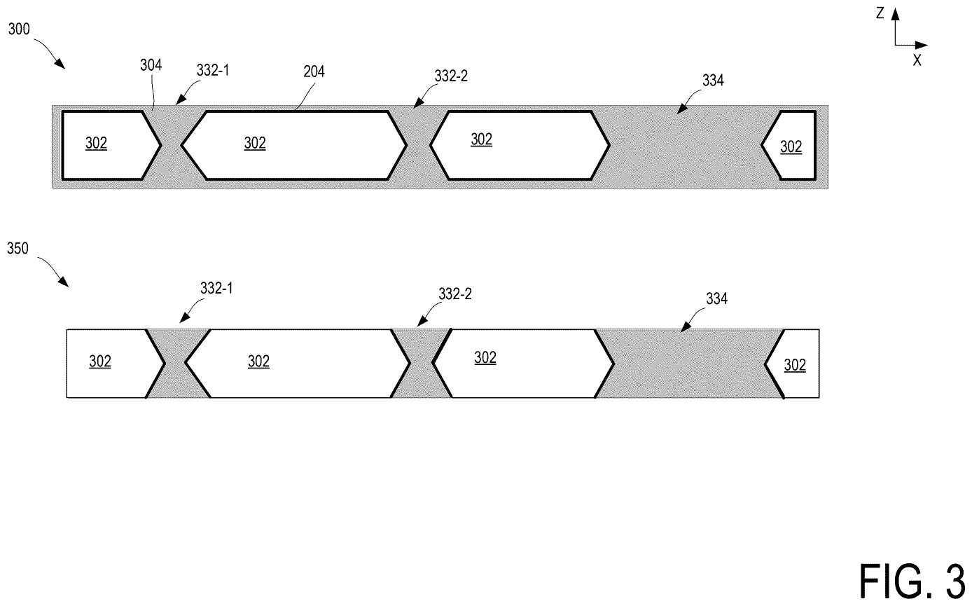

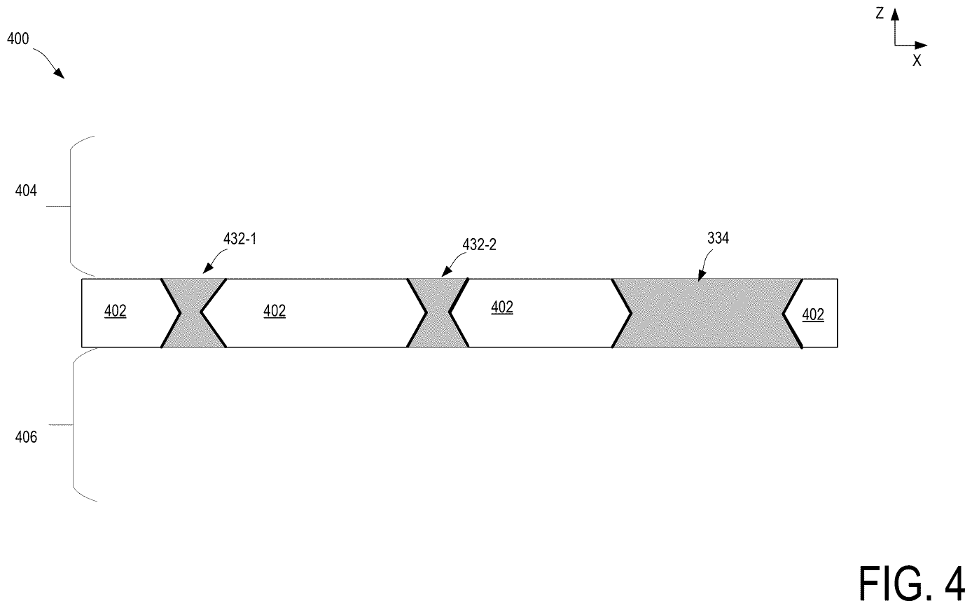

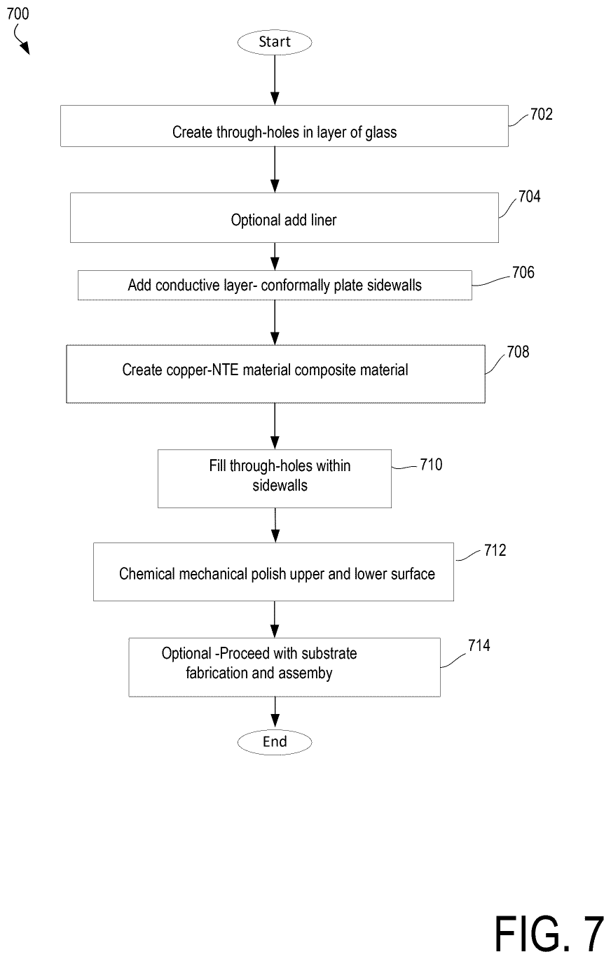

With continued reference to FIG. 1, FIGS. 2-3 are simplified cross-sectional illustrations of various exemplary stages of fabrication of copper-NTE filled through-glass vias, in accordance with various embodiments. FIGS. 4-6 are simplified cross-sectional illustrations of various exemplary use cases for copper-NTE filled through-glass vias, in accordance with various embodiments. FIG. 7 illustrates an example method 700 for copper-NTE filled through-glass vias.

Image 200 depicts a layer of glass 202 or glass core prior to creation of the TGVs and cavities. The layer of glass 202 can be, in various embodiments, a reconstituted wafer with glass cores, an entire uncut panel, or a diced panel.

In embodiments that manufacture a panel at a time, the X length of a layer of glass, and a corresponding Y length (defining an area in a top down or plan view) may be in a range of a first length (e.g., X) in a range of 10 millimeters to 700 millimeters, and a second length (e.g., Y) in a range of 10 millimeters to 700 millimeters, the first length perpendicular to the second length. The composition of the glass 202/302/402/502/602 is described above in connection with FIG. 1.

Image 230 depicts (at 702) the through-holes or TGVs created in the layer of glass 202. As mentioned above, the laser changes the chemistry of the glass, allowing the area to be etched away, which may result in a slope or taper, as described in connection with embodiment 130. In image 230, the first TGV 232-1/332-1 and a second TGV 232-2/332-2 are illustrated. In practice, TGV 232-1 and 232-2 may be two of a plurality of TGVs. An optional cavity 234/334 may also be created at this stage. Optional cavity 234 may be large enough (e.g., minimum diameter) to fit an IC die or other component into at a later fabrication stage. In various embodiments, the optional cavity 234/334 can have a diameter in a range between 1-30 millimeters, inclusive.

As shown in image 250, at 706, a conductive layer 104 is added, illustrated using a thicker line than the boundary of the glass 202 in image 230. In various embodiments, the conductive layer is adjacent to the glass 102, as shown. In other embodiments, the conductive layer 104 is overlaid on an optional liner (not shown) (at 704); in these embodiments, the liner is adjacent to the glass 102 on a first side and is adjacent to the conductive layer 104 on an opposite side (said differently, the optional liner may be sandwiched between the conductive layer 104 and the glass 102).

Image 300 illustrates that (at 710) embodiments fill the cavity of the through-holes or TGVs with a fill material 304 (e.g., cavity 106 and/or cavity 136 are filled with the fill material) that is electrically conductive. As used herein, the verb “fill” means to distribute sufficient fill material therein to enable electrical communication or a continuous electrical path between the upper surface 101 and the lower surface 103, and a TGV that is filled with fill material has the fill material sufficiently distributed in the cavity to enable electrical communication between the upper surface 101 and the lower surface 103.

Available solutions fill the cavity of the TGV with a method called a copper bath, or copper electroplating solution; the copper bath generally comprises copper, sulfuric acid, some organic chemicals, an accelerator, a brightness oppressor and some proprietary materials. This copper electroplating solution results in TGVs that are filled with a fill material that is mainly copper. As mentioned above, these available solutions result in TGV architectures with a large CTE mismatch between the TGV and the glass core. For example, the CTE of Cu is 17.5 ppm/K (parts per million per degree Kelvin), and the CTE of glass may be in a range of 2-10 ppm/K, inclusive, this mismatch in the CTE is considered large (i.e., more than 10 ppm/K is large).

In contrast to the available solutions, in method 700, the provided embodiments add a negative thermal expansion (NTE) material to the copper bath to thereby create a copper-NTE bath at 708. A negative thermal expansion (NTE) material shrinks or contracts upon heating. The NTE particles are suspended in the copper electroplating solution at 708, and the layer of glass with the through-holes plated with the conductive material is immersed in the electroplating solution with the NTE material. The copper-NTE bath fills the TGVs (e.g., TGV 332-1 and TGV 332-2) that with the fill material 304 that is the composite structure of copper and one or more NTE materials. The composite structure of the fill material 304 reduces the CTE mismatch between the conductive material within the TGV and the glass of the glass core surrounding the TGV. The reduction in the CTE mismatch between the TGV fill material and the glass core advantageously reduces stress during the manufacturing process (e.g., during annealing cycles) and mitigates glass core strength reduction. The desired or target CTE for the fill material in the TGV can be used to inform the selection of the specific NTE to use and the percentage of the NTE to use.

For example, in some embodiments, the NTE material is zirconium tungstate (ZrW2O8). Adding the zirconium tungstate reduces the CTE of the fill material. In a non-limiting example, adding a 10% (+/−3%) volume of zirconium tungstate deposit in copper may reduce the CTE of the fill material to 15 ppm/K +/−10%.

In other embodiments, the NTE material can be Hafnium tungstate (HfW2O8) or Zirconium-Molybdate-Oxide (ZrMo2O8). In some embodiments, the NTE material may have the chemical formula Zr1-xHfxW2O8, ZrW2-xMoxO8; and Zr1-xMxW2O8-y (wherein M=Sc, In, or Y, x is a number and y is another number). All of these NTE materials have the same crystal structure as ZrW2O8 and exhibit NTE over a wide temperature range. In yet another embodiment, the NTE material may comprise AM2O7 (wherein A=U, Th, Zr, Hf, or Sn; and M=P or V).

In various embodiments, the fill material has at least 40% copper, to optimize the electrically conductive properties of the copper, and the remainder of the fill material comprises NTE material. Said differently, embodiments have a fill material comprising less than 50%. Practice of embodiments can be identified by identifying (e.g., using EDS spectroscopy) any amount of a NTE material, or by identifying greater than 1% of a NTE material in the fill material in the TGVs. In some embodiments, the amount of NTE material is between 1% and 20%, inclusive; in other embodiments, the amount of NTE material is between 1% and 60%, inclusive.

At 712, a chemical mechanical polish (CMP) may be performed on the embodiment in image 300 to remove the copper-NTE material to expose the glass surfaces 101/103, as shown in the embodiment in image 350.

The practice of embodiments can be identified by visually inspecting TEM or SEM images of cross-sectional views of filled TGVs, as illustrated in embodiments 100 and 130, combined with compositional analysis of the fill material, to detect the herein described composite structures including NTEs within the TGVs.

As illustrated in image 400, embodiments may undergo further semiconductor manufacturing processing at 714, such as having one or more layers of a semiconductor substrate built on the upper surface (e.g., 404) or on its lower surface (e.g., 406) of the embodiment in image 350. Continuing with this simplified example, in image 500 and multi-die assembly 600, the embodiment from image 350 is shown attached to or sandwiched within a semiconductor substrate: the semiconductor substrate can be described as semiconductor substrate 504/604 includes one or more dielectric layers 508/608 with redistribution layers (RDL) or conductive traces 528/628 and vias 526/626 patterned therein on the upper surface of the embodiment shown in image 350 and semiconductor substrate 506/606 includes one or more dielectric layers 508/608 with redistribution layers (RDL) or conductive traces 528/628 and vias 526/626 patterned therein on the lower surface of the embodiment shown in image 350.

The dielectric material 508/608 may be any insulating material, such as, a suitable nitride or oxide, such as a SiOx, silicon dioxide (SiO₂), SiOxNy, carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a dielectric layer comprises a photo-imageable dielectric (PID). In some embodiments, the dielectric material comprises an Ajinomoto Build-Up film (ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

Note that the optional cavity 334 may initially be filled with the fill material. In practice, the fill material from this optional cavity 432 may be removed, such as by laser drilling or ablation, and an integrated circuit or component may be placed therein and electrically attached, e.g., in building a system or package assembly. Some non-limiting examples of ICs and components that may be placed in the cavity 432 include a memory or high bandwidth memory, trench capacitors, central processing unit, photonic integrated circuit, graphics processing unit, etc.

The conductive material used for RDL traces 628 and vias 626 may comprise a metal (e.g., copper, aluminum, nickel, cobalt, iron, tin, gold, silver, or combinations thereof) or another suitable conductive material.

The optional cavity 334 was opened and filled with an IC, PIC, or other component, and electrically attached at 510/610 and at 512/612, as known in the art. As intended, the provided copper-NTE filled through glass vias in the glass core 502 provide a landing and contact for vias and provide an electrical pathway from an upper surface 503/603 of the substrate to a lower surface 505/605 of the substrate.

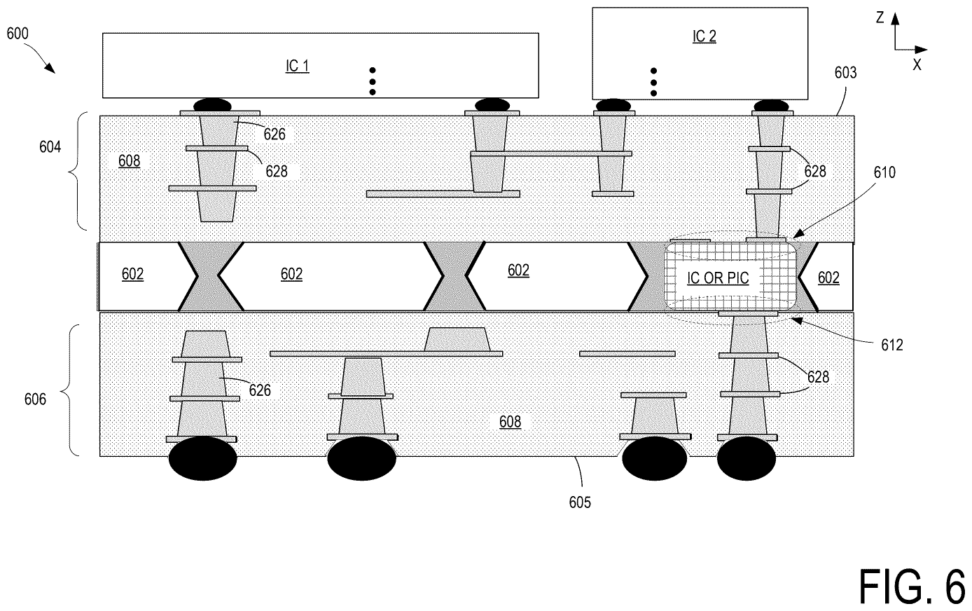

In FIG. 6, an exemplary multi-die assembly 600 is depicted with first IC and a second IC attached to the upper surface 603 and solder attached in the openings created for them at the lower surface 605. The die IC1 and IC 2, may be unpackaged integrated circuit die, and may alternatively be referred to as chips, chiplets, chip complexes, or chiplet complexes. While the terms die, chip, and chiplet may be used interchangeably, the term chiplet is sometimes used to refer to an integrated circuit die that implements a subset of the functionality of a larger integrated circuit component. Although the illustration depicts the chiplets as having uniform dimensions, in practice, chiplet dimensions (lateral dimensions, as well as thickness) and shape can vary among chiplets; moreover, the chiplets may vary by type/functionality (e.g., compute, memory, I/O, power management (controlling the delivery of power and/or providing power to components).

In further fabrication steps, the die IC 1 and IC 2 may be stabilized within an encapsulant such as a molding compound, dielectric materials, metal, ceramic, plastic, or a combination thereof. Also, an underfill may be employed below IC 1 and IC 2 to surround the solder bumps. A variety of underfill materials can be used, generally they are non-conducting (electrically) and reduce thermomechanical stress. Underfill materials may take the form of a liquid pre-polymer with a filler such as silica, alumina, or boron nitride. The underfill can be cured to solidify it.

Additionally, as part of a thermal management solution, a thermal conduction layer interface material (TIM) (not shown) may be located over the encapsulant and/or over the die. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

Thus, various non-limiting embodiments of methods and architectures for copper-NTE filled TGVs have been described. Embodiments exhibit distinct features in SEM images, not limited to the chemical identity of the fill material, as described herein. The following description provides additional details and context for various die and various package assembly and device configurations that can be created based on or using the provided embodiments.

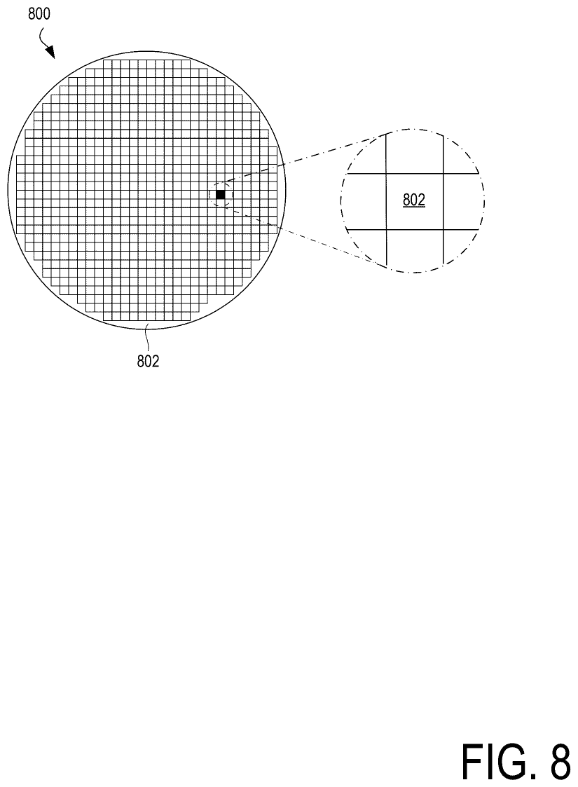

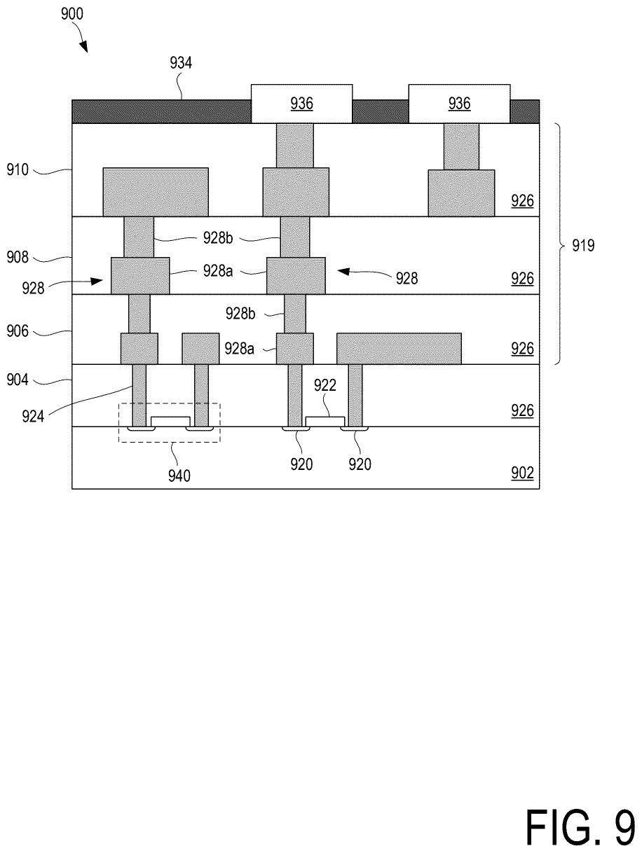

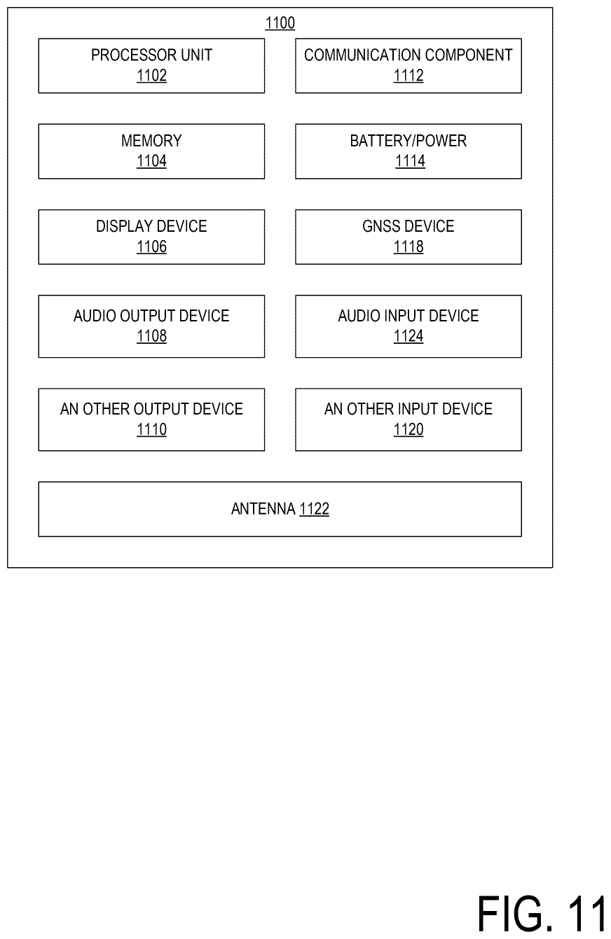

FIG. 8 is a top view of a wafer 800 and dies 802 that may be included in any of the embodiments disclosed herein. The wafer 800 may be composed of semiconductor material and may include one or more dies 802 formed on a surface of the wafer 800. After the fabrication of the integrated circuit components on the wafer 800 is complete, the wafer 800 may undergo a singulation process in which the dies 802 are separated from one another to provide discrete “chips” or destined for a packaged integrated circuit component. The individual dies 802, comprising an integrated circuit component, may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 802. For example, a memory array formed by multiple memory devices may be formed on a same die 802 as a processor unit (e.g., the processor unit 1102 of FIG. 11) or other logic that is configured to store information in the memory devices or execute instructions stored in the memory array. In some embodiments, a die 802 may be attached to a wafer 800 that includes other die, and the wafer 800 is subsequently singulated, this manufacturing procedure is referred to as a die-to-wafer assembly technique.

FIG. 9 is a cross-sectional side view of an integrated circuit 900 that may be included in any of the embodiments disclosed herein. One or more of the integrated circuits 900 may be included in one or more dies 802 (FIG. 8). The integrated circuit 900 may be formed on a die substrate 902 (e.g., the wafer 800 of FIG. 8) and may be included in a die (e.g., the die 802 of FIG. 8).

The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit 900 may be used. The die substrate 902 may be part of a singulated die (e.g., the dies 802 of FIG. 8) or a wafer (e.g., the wafer 800 of FIG. 8).

The integrated circuit 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920.

The gate 922 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may comprise a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be conducted to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuits having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines of interconnect structures 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit 900 with another component (e.g., a printed circuit board). The integrated circuit 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit 900 is a double-sided die, the integrated circuit 900 may include another metallization stack (not shown) on the opposite side of the device layer(s) 904. This metallization stack may include multiple interconnect layers as discussed above with reference to the interconnect layers 906-910, to provide electrically conductive paths (e.g., including conductive lines and vias) between the device layer(s) 904 and additional conductive contacts (not shown) on the opposite side of the integrated circuit 900 from the conductive contacts 936.

In other embodiments in which the integrated circuit 900 is a double-sided die, the integrated circuit 900 may include one or more through-silicon vias (TSVs) through the die substrate 902; these TSVs may make contact with the device layer(s) 904, and may provide electrically conductive paths between the device layer(s) 904 and additional conductive contacts (not shown) on the opposite side of the integrated circuit 900 from the conductive contacts 936. In some embodiments, TSVs extending through the substrate can be used for routing power and ground signals from conductive contacts on the opposite side of the integrated circuit 900 from the conductive contacts 936 to the transistors 940 and any other components integrated into the integrated circuit 900 die, and the metallization stack 919 can be used to route I/O signals from the conductive contacts 936 to transistors 940 and any other components integrated into the integrated circuit 900 die.

Multiple integrated circuits 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

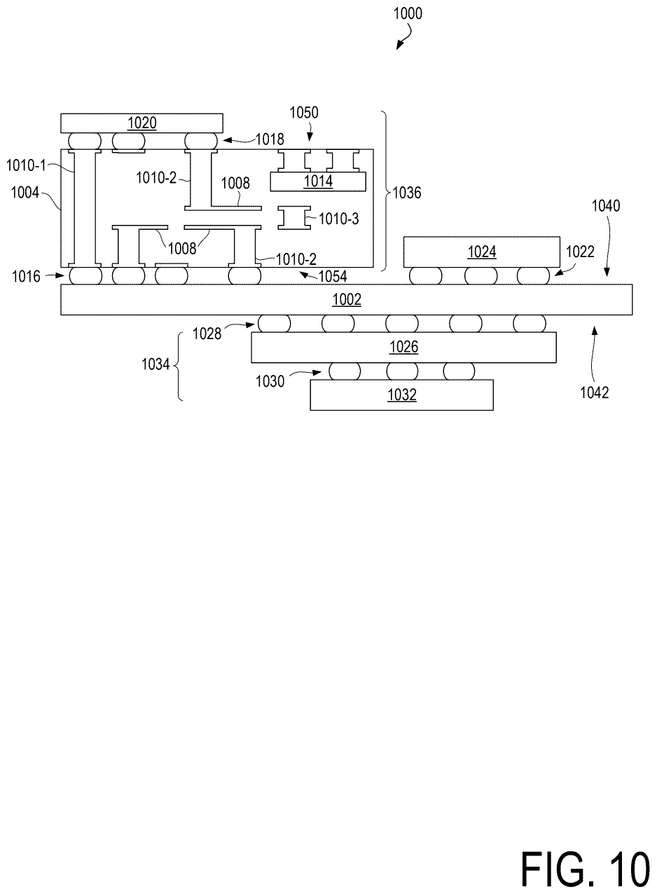

FIG. 10 is a cross-sectional side view of a microelectronic assembly 1000 that may include any of the embodiments disclosed herein. The microelectronic assembly 1000 includes multiple integrated circuit components disposed on a circuit board 1002 (which may be a motherboard, system board, mainboard, etc.). The microelectronic assembly 1000 may include components disposed on a first face 1040 of the circuit board 1002 and an opposing second face 1042 of the circuit board 1002; generally, components may be disposed on one or both faces 1040 and 1042.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The microelectronic assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpackaged integrated circuit component that includes one or more integrated circuit dies (e.g., the die 802 of FIG. 8, the integrated circuit 900 of FIG. 9) and/or one or more other suitable components.

The unpackaged integrated circuit component 1020 comprises solder bumps attached to contacts on the die. The solder bumps allow the die to be directly attached to the interposer 1004. In embodiments where the integrated circuit component 1020 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through-silicon vias (TSV) extending through the silicon interposer can connect connections on the first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art.

The integrated circuit assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the embodiments disclosed herein. For example, any suitable ones of the components of the electrical device 1100 may include one or more of the microelectronic assemblies 1000, integrated circuit components 1020, integrated circuits 900, integrated circuit dies 802, or structures disclosed herein. A number of components are illustrated in FIG. 11 as included in the electrical device 1100, but any one or more of these components may be omitted or duplicated, as suitable for the application. In some embodiments, some or all the components included in the electrical device 1100 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1 ), Level 2 (L2 ), Level 3 (L3 ), Level 4 (L4 ), Last Level Cache (LLC)) and may include embedded dynamic random-access memory (eDRAM) or spin transfer torque magnetic random-access memory (STT-MRAM).

In some embodiments, the electrical device 1100 can comprise one or more processor units 1102 that are heterogeneous or asymmetric to another processor unit 1102 in the electrical device 1100. There can be a variety of differences between the processor units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include another output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include another input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “electronic component” can refer to an active electronic circuit (e.g., processing unit, memory, storage device, FET) or a passive electronic circuit (e.g., resistor, inductor, capacitor).

As used herein, the term and “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die; the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” followed by a list of items recited or stated as having a trait, feature, etc., means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus comprising: a layer of glass having an upper surface and a lower surface; a through-hole formed in the layer of glass; and a material distributed in the through-hole to provide a continuous electrical path between the upper surface to the lower surface; wherein the material comprises copper and 1% or more of a negative thermal expansion (NTE) material.

Example 2 includes the subject matter of Example 1, wherein the material comprises between 1% and 20%, inclusive, of the NTE material.

Example 3 includes the subject matter of Example 1, wherein the material comprises between 1% and 60% of the NTE material, inclusive.

Example 4 includes the subject matter of any one of Examples 1-3, wherein the NTE material comprises zirconium tungstate (ZrW2O8).

Example 5 includes the subject matter of any one of Examples 1-3, wherein the NTE material comprises hafnium tungstate (HfW2O8).

Example 6 includes the subject matter of any one of Examples 1-3, wherein the NTE material comprises Zirconium-Molybdate-Oxide (ZrMo2O8).

Example 7 includes the subject matter of any one of Examples 1-3, wherein the NTE material comprises a chemical formula of Zr1-xHfxW2O8, ZrW2-xMoxO8, or Zr1-xMxW2O8-y (wherein M=Sc, In, or Y, x is a number and y is another number).

Example 8 includes the subject matter of any one of Examples 1-7, wherein the through-hole has a continuous sidewall, and further comprising: a conductive layer conformal to the continuous sidewall; wherein the material is within the conductive layer.

Example 9 includes the subject matter of Example 8, wherein the conductive layer has a thickness of 20 nanometers +/−5 nanometers.

Example 10 includes the subject matter of Example 8, wherein the conductive layer has a thickness in a range of 20 nanometers-5 nanometers to 2000 nanometers.

Example 11 is a multi-die assembly, comprising: a first semiconductor substrate including a plurality of dielectric layers and redistribution layers therein; a conductive via in the first semiconductor substrate, the conductive via electrically connected to a redistribution layer and exposed at a lower surface of the first semiconductor substrate; a layer of glass attached to the lower surface of the first semiconductor substrate, the layer of glass comprising a plurality of through-glass vias; wherein individual through-glass vias comprise a continuous sidewall that is conformally plated with a conductive material, and comprises a fill material within the conductive material; wherein the fill material comprises copper with 1% or more of a compound containing zirconium or tungsten; and a second semiconductor substrate attached to a lower surface of the layer of glass; wherein the conductive via is electrically coupled to the fill material in one through-glass via of the plurality of through-glass vias.

Example 12 includes the subject matter of Example 11, further comprising: an integrated circuit die attached to an upper surface of the first semiconductor substrate; and an electrical pathway from the integrated circuit die through a through-glass via of the plurality of through glass vias to a lower surface of the layer of glass.

Example 13 includes the subject matter of Example 12, wherein the electrical pathway further extends to a solder opening on the lower surface of the second semiconductor substrate.

Example 14 includes the subject matter of Example 12, wherein the integrated circuit die is a first integrated circuit die, and further comprising: a second integrated circuit die attached to the upper surface of the first semiconductor substrate; wherein the first integrated circuit die is in operable communication with the second integrated circuit die; and a motherboard attached to a lower surface of the second semiconductor substrate.

Example 15 includes the subject matter of Example 12, further comprising an encapsulant overlaid on the first integrated circuit die and second integrated circuit die.

Example 16 includes the subject matter of any one of Examples 11-15 wherein the fill material comprises zirconium tungstate (ZrW2O8), hafnium tungstate (HfW2O8), or zirconium-Molybdate-Oxide (ZrMo2O8).

Example 17 is a method comprising: creating a plurality of through-holes in a layer of glass having an upper surface and a lower surface, wherein through-holes are characterized by a respective sidewall; adding a conductive material to the layer of glass, to thereby create a respective plurality of sidewalls that are conformally plated with the conductive material; creating an electroplating solution that includes a composite material, the composite material comprising copper and at least 1% of a negative thermal expansion (NTE) material; and immersing the layer of glass in the electroplating solution to thereby fill the plurality of sidewalls that are conformally plated with the composite material.

Example 18 includes the subject matter of Example 17, wherein the NTE material comprises zirconium tungstate (ZrW2O8), hafnium tungstate (HfW2O8), or zirconium-Molybdate-Oxide (ZrMo2O8).

Example 19 includes the subject matter of Example 17 or Example 18, further comprising polishing the upper surface and the lower surface to expose the layer of glass.

Example 20 includes the subject matter of Example 19, further comprising: adding a first semiconductor substrate with redistribution layers therein on the upper surface; adding a second semiconductor substrate with redistribution layers therein on the lower surface; attaching an integrated circuit die on an upper surface of the first semiconductor substrate; and creating at least one electrical path from the integrated circuit die through a through-glass via to a lower surface of the second semiconductor substrate.

What is claimed is:

1. An apparatus comprising:
a layer of glass having an upper surface and a lower surface;
a through-hole formed in the layer of glass; and
a material distributed in the through-hole to provide a continuous electrical path between the upper surface to the lower surface;
wherein the material comprises copper and 1% or more of a negative thermal expansion (NTE) material.

2. The apparatus of claim 1, wherein the material comprises between 1% and 20%, inclusive, of the NTE material.

3. The apparatus of claim 1, wherein the material comprises between 1% and 60% of the NTE material, inclusive.

4. The apparatus of claim 1, wherein the NTE material comprises zirconium tungstate (ZrW2O8).

5. The apparatus of claim 1, wherein the NTE material comprises hafnium tungstate (HfW2O8).

6. The apparatus of claim 1, wherein the NTE material comprises Zirconium-Molybdate-Oxide (ZrMo2O8).

7. The apparatus of claim 1, wherein the NTE material comprises a chemical formula of Zr1-xHfxW2O8, ZrW2-xMoxO8, or Zr1-xMxW2O8-y;
wherein M=Sc, In, or Y, and x is a number and y is another number.

8. The apparatus of claim 1, wherein the through-hole has a continuous sidewall, and further comprising:
a conductive layer conformal to the continuous sidewall;
wherein the material is within the conductive layer.

9. The apparatus of claim 8, wherein the conductive layer comprises copper with a thickness of 20 nanometers plus or minus 5 nanometers.

10. The apparatus of claim 8, wherein the conductive layer has a thickness in a range of 20 nanometers-5 nanometers to 2000 nanometers.

11. A multi-die assembly, comprising:
a first semiconductor substrate including a plurality of dielectric layers and redistribution layers therein;
a conductive via in the first semiconductor substrate, the conductive via electrically connected to a redistribution layer and exposed at a lower surface of the first semiconductor substrate;
a layer of glass attached to the lower surface of the first semiconductor substrate, the layer of glass comprising a plurality of through-glass vias;
wherein individual through-glass vias comprise a continuous sidewall that is conformally plated with a conductive material, and comprises a fill material within the conductive material;
wherein the fill material comprises copper with 1% or more of zirconium (Zr) or tungsten (W); and
a second semiconductor substrate attached to a lower surface of the layer of glass;
wherein the conductive via is electrically coupled to the fill material in one through-glass via of the plurality of through-glass vias.

12. The multi-die assembly of claim 11, further comprising:
an integrated circuit die attached to an upper surface of the first semiconductor substrate; and
an electrical pathway from the integrated circuit die through a through-glass via of the plurality of through glass vias to a lower surface of the layer of glass.

13. The multi-die assembly of claim 12, wherein the electrical pathway further extends to a solder opening on the lower surface of the second semiconductor substrate.

14. The multi-die assembly of claim 12, wherein the integrated circuit die is a first integrated circuit die, and further comprising:
a second integrated circuit die attached to the upper surface of the first semiconductor substrate;
wherein the first integrated circuit die is in operable communication with the second integrated circuit die; and
a motherboard attached to a lower surface of the second semiconductor substrate.

15. The multi-die assembly of claim 12, further comprising an encapsulant overlaid on the first integrated circuit die and second integrated circuit die.

16. The multi-die assembly of claim 11 wherein the fill material comprises zirconium tungstate (ZrW2O8), hafnium tungstate (HfW2O8), or zirconium-Molybdate-Oxide (ZrMo2O8).

17. A method comprising:
creating a plurality of through-holes in a layer of glass having an upper surface and a lower surface, wherein through-holes are characterized by a respective sidewall;
adding a conductive material to the layer of glass, to thereby create a respective plurality of sidewalls that are conformally plated with the conductive material;
creating an electroplating solution that includes a composite material, the composite material comprising copper and at least 1% of a negative thermal expansion (NTE) material; and
immersing the layer of glass in the electroplating solution to thereby fill the plurality of sidewalls that are conformally plated with the composite material.

18. The method of claim 17, wherein the NTE material comprises zirconium tungstate (ZrW2O8), hafnium tungstate (HfW2O8), or zirconium-Molybdate-Oxide (ZrMo2O8).

19. The method of claim 17, further comprising polishing the upper surface and the lower surface to expose the layer of glass.

20. The method of claim 19, further comprising:
adding a first semiconductor substrate with redistribution layers therein on the upper surface;
adding a second semiconductor substrate with redistribution layers therein on the lower surface;
attaching an integrated circuit die on an upper surface of the first semiconductor substrate; and
creating at least one electrical path from the integrated circuit die through a through-glass via to a lower surface of the second semiconductor substrate.
